(19) United States
(12) Patent Application Publication
(10) Pub. No.: US 2012/0062275 A1
(43) Pub. Date: Mar. 15, 2012

(54) INTERFACE CIRCUIT

(75) Inventors: Tsuyoshi HIRAKI, Osaka (JP); Shinya Miyazaki, Osaka (JP); Wataru Tamachi, Osaka (JP); Keisuke Nakahira, Osaka (JP); Kazuya Hatooka, Hyogo (JP); Jiro Ikemura, Osaka (JP)

(73) Assignee: Panasonic Corporation, Osaka (JP)

(21) Appl. No.: 13/297,764

(22) Filed: Nov. 16, 2011

Related U.S. Application Data
(63) Continuation of application No. PCT/JP2009/006322, filed on Nov. 24, 2009.

(30) Foreign Application Priority Data
May 29, 2009 (JP) 2009-131479

(51) Int. Cl. H03K 19/003

(52) U.S. Cl. 326/30

(57) ABSTRACT

In performing calibration, a control circuit in a calibration circuit of an interface circuit controls a selector so that voltages V1, VREF or voltages V1, V2 are applied to a comparator. The two voltages input to the comparator is switched between positive and negative inputs of the comparator. In both of the states, the control circuit obtains signal values of variable-resistor control signals UPCODE, DNCODE at a time when an output of the comparator is changed, and obtains calibration data to control the resistance value of the terminating resistor by using a mean value of the obtained signal values.

### CROSS-REFERENCE TO RELATED APPLICATION

This is a continuation of PCT International Application PCT/JP2009/006322 filed on Nov. 24, 2009, which claims priority to Japanese Patent Application No. 2009-131479 filed on May 29, 2009. The disclosures of these applications including the specifications, the drawings, and the claims are hereby incorporated by reference in their entirety.

### BACKGROUND

The present invention relates to interface circuits of, for example, memory interfaces, specifically to the technique of calibrating the resistance value of a terminating resistor for bus termination.

Interface circuits generally use a stub series termination logic (SSTL) and active termination for termination of buses. The active termination is also called on-chip termination, and active terminating resistors (hereinafter referred to as “terminating resistors”) in a chip are used to terminate the buses. The active termination has better signal transmission characteristics and a higher data rate than the SSTL.

In the active termination, the resistance value shift of the terminating resistors degrades the signal transmission characteristics. As the data transmission rate increases, the influence of the resistance value shift of the terminating resistors on the signal transmission characteristics becomes more pronounced. Thus, to reduce the degradation of the signal transmission characteristics, it is required to calibrate accurately the terminating resistors to have preferable resistance values.

For example, Japanese Patent Publication No. 2003-280779 discloses a calibration circuit which includes two comparators, first and second variable resistors, a dummy variable resistor identical to the first variable resistor, a first control-code generation circuit, and a second control-code generation circuit, wherein the calibration circuit is capable of calibrating the resistance value of a terminating resistor independently of process steps, voltages, or temperatures. One of the comparators compares a first node at which the first variable resistor is connected to an external resistor with a reference voltage VREF, and the other one of the comparators compares the first node with a second node at which the dummy variable resistor is connected to the second variable resistor. Based on the results output from the two comparators, the first control-code generation circuit and the second control-code generation circuit generate control codes.

Moreover, for example, Japanese Patent No. 3609363 discloses an interface circuit configured to correct variations in resistance value of a terminating resistor, the variations being caused by, for example, a change in surrounding temperature. While transmission and reception of data are stopped, a node 1 to which a plurality of resistive elements are commonly connected is compared by using two comparators with an upper limit reference voltage and a lower limit reference voltage which are computed from a range of the resistance value of a preferable terminating resistor. If the node 1 is out of the range, correction is performed so that the node 1 is within the range.

### SUMMARY

However, the conventional circuit configurations use comparators including analog devices to calibrate terminating resistors. The comparators usually include offsets having different values depending on the comparators due to the influence of variations of the analog devices. Thus, the accuracy of voltage comparison by the comparators is not ensured, so that the resistance values of the terminating resistors cannot necessarily be calibrated to have preferable resistance values, which degrades the signal transmission characteristics.

In view of the foregoing, an example interface circuit of the present invention may be capable of calibrating the resistance value of a terminating resistor without being influenced by variations of analog devices.

A first embodiment of the present invention is an interface circuit configured to calibrate a resistance value of a terminating resistor, the interface circuit comprising: a variable resistance section serving as the terminating resistor; a pad to which a reference resistor is externally connected; and a calibration circuit which is connected to the pad, and is configured to output calibration data to the variable resistance section to control the resistance value, the calibration circuit including a dummy variable resistor connected between a first power source and the pad, first and second variable resistors connected in series between the first power source and a second power source, a comparator having a positive input and a negative input, a selector configured to receive a voltage at a first node between the dummy variable resistor and the pad, a voltage at a second node between the first and second variable resistors, and a reference voltage, to select, among the voltages, respective voltages to be applied to the positive input and the negative input of the comparator, and to output the selected voltages, and a control circuit configured to receive the output of the comparator, and to output a first variable-resistor control signal for controlling resistance values of the dummy variable resistor and the first variable resistor, a second variable-resistor control signal for controlling a resistance value of the second variable resistor, and a selector control signal for controlling the selector, wherein in performing calibration, the control circuit monitors the output of the comparator while varying the first or second variable-resistor control signal in a state of controlling the selector by the selector control signal so that the voltage at the first node and the reference voltage, or the voltage at the first node and the voltage at the second node are applied to the comparator, and obtains the calibration data based on a signal value of the first or second variable-resistor control signal at a time when the output of the comparator is changed, and the control circuit obtains the signal value of the first or second variable-resistor control signal at the time when the output of the comparator is changed in a state where the voltage at the first node and the reference voltage, or the voltage at the first node and the voltage at the second node are input to the positive and negative inputs of the comparator, respectively, and in a state where the voltage at the first node and the reference voltage, or the voltage at the first node and the voltage at the second node are input to the negative and positive inputs of the comparator, respectively, and obtains the calibration data using a mean value of the obtained signal values.

With this embodiment, when the comparator compares the voltage at the first node with the reference voltage or the voltage at the first node with the second node, the two voltages input to the comparator are switched between the positive and negative inputs. In both of the states, the signal value of the first or second variable-resistor control signal at the time when the output of the comparator is changed is obtained, and a mean value of the obtained signal values is used to obtain calibration data to control the resistance value of the terminating resistor. With this operation, calibration data with a high degree of accuracy can be obtained without being influenced by the offset of the comparator, and thus, the terminating resistor can be calibrated to have a preferable resistance value without being influenced by variations of analog devices, so that it is possible to ensure preferable signal transmission characteristics.

A second embodiment of the present invention is an interface circuit configured to calibrate a resistance value of a terminating resistor, the interface circuit including: a variable resistance section serving as the terminating resistor; a pad to which a reference resistor is externally connected; and a calibration circuit which is connected to the pad, and is configured to output calibration data to the variable resistance section to control the resistance value, the calibration circuit including a dummy variable resistor connected between a first power source and the pad, first and second variable resistors connected in series between the first power source and a second power source, a comparator having a positive input and a negative input, a selector configured to receive a voltage at a first node between the dummy variable resistor and the pad, a voltage at a second node between the first and second variable resistors, and a reference voltage, to select, among the voltages, respective voltages to be applied to the positive input and the negative input of the comparator, and to output the selected voltages, a D/A converter which is used to cancel an offset of the comparator, an adder configured to add an output of the D/A converter to the positive input or the negative input of the comparator, and a control circuit configured to receive the output of the comparator, and to output a first variable-resistor control signal for controlling resistance values of the dummy variable resistor and the first variable resistor, a second variable-resistor control signal for controlling a resistance value of the second variable resistor, a selector control signal for controlling the selector, and an offset cancellation signal to be input to the DA converter, wherein in performing calibration, the control circuit monitors the output of the comparator while varying the first or second variable-resistor control signal in a state of controlling the selector by the selector control signal so that the voltage at the first node and the reference voltage, or the voltage at the first node and the voltage at the second node are applied to the comparator, and obtains the calibration data based on a signal value of the first or second variable-resistor control signal at a time when the output of the comparator is changed, and before the calibration data is obtained, the control circuit monitors the output of the comparator while varying the offset cancellation signal in a state of controlling the selector by the selector control signal so that the reference voltage is applied to both the positive and negative inputs of the comparator, and obtains offset cancellation data based on a signal value of the offset cancellation signal at the time when the output is changed, and the control circuit supplies the offset cancellation data to the D/A converter in performing the calibration.

With this embodiment, before obtaining the calibration data, the reference voltage is applied to both the positive and negative inputs of the comparator, and an output of the D/A converter after reception of an offset cancellation signal is added to one of the positive input or the negative input by the adder. With this state, a signal value of an offset cancellation signal at the time when the output of the comparator is changed is obtained, and based on the obtained signal value, offset cancellation data is obtained. When calibration is performed, the offset cancellation data is supplied to the D/A converter. With this operation, calibration data with a high degree of accuracy can be obtained without being influenced by the offset of the comparator, and thus, the terminating resistor can be calibrated to have a preferable resistance value without being influenced by variations of analog devices, so that it is possible to ensure preferable signal transmission characteristics.

According to the present invention, calibration data with a high degree of accuracy can be obtained without being influenced by the offset of the comparator, and thus, the terminating resistor can be calibrated to have a preferable resistance value without being influenced by variations of analog devices, so that it is possible to ensure preferable signal transmission characteristics.

### BRIEF DESCRIPTION OF THE DRAWINGS

FIG. 1 is a view schematically illustrating a configuration of an interface circuit according to a first embodiment to a third embodiment.

FIG. 2 is a view schematically illustrating a configuration in which the interface circuit of FIG. 1 serves as a memory interface circuit.

FIG. 3 is a circuit diagram illustrating a configuration of a calibration circuit according to the first embodiment.

FIG. 4 is a view illustrating an example circuit configuration of a variable resistor.

FIG. 5 is a circuit diagram illustrating a configuration of a calibration circuit according to the second embodiment.

FIG. 6 is a circuit diagram illustrating a configuration of a calibration circuit according to the third embodiment.

### DETAILED DESCRIPTION

Embodiments of the present invention will be described below with reference to the drawings. In the following embodiments, like reference characters are used in the drawings to designate identical or equivalent elements, and explanation thereof is not repeated.

### First Embodiment

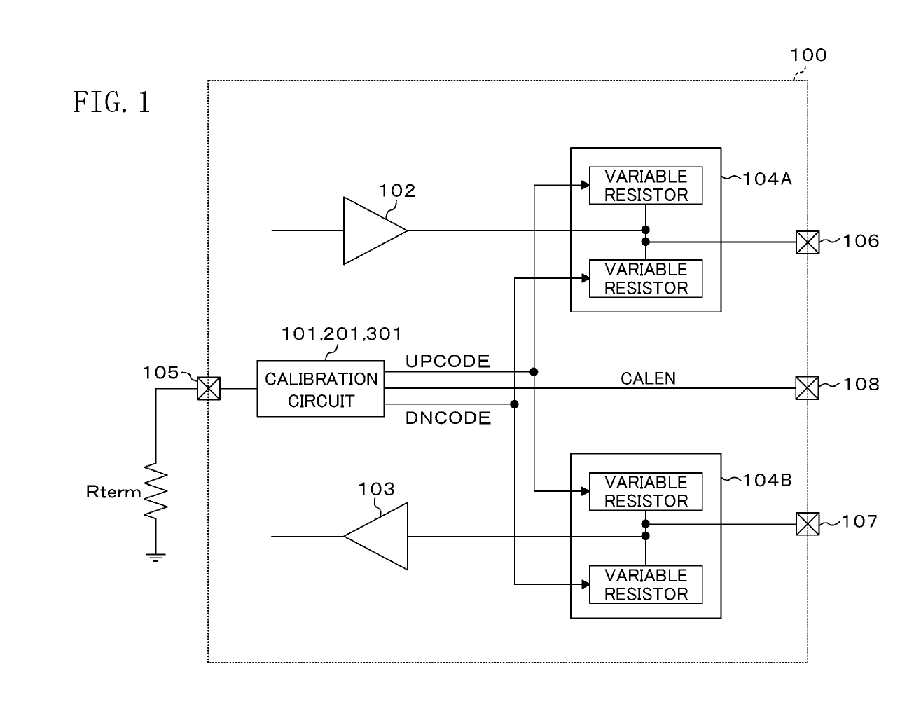

FIG. 1 is a circuit diagram schematically illustrating a configuration of an interface circuit according to a first embodiment. An interface circuit 100 illustrated in FIG. 1 includes a transmitter circuit 102, a receiver circuit 103, a transmission pad 106 connected to a data bus, and a reception pad 107 connected to a data bus. Between the transmitter circuit 102 and the transmission pad 106, and between the receiver circuit 103 and the reception pad 107, variable resistance sections 104A, 104B are provided, respectively. Each of the variable resistance sections 104A, 104B serves as active terminating resistor of the bus. The interface circuit 100 further includes a calibration circuit 101 (201, 301) to calibrate the active terminating resistors. The calibration circuit 101 (201, 301) is connected to an externally provided reference resistor Rterm via a pad 105. After performing calibration operation, the calibration circuit 101 (201, 301) controls the resistance values of the variable resistance sections 104A, 104B by first and second control codes UPCODE, DNCODE serving as calibration data. Each of the first and second control codes UPCODE, DNCODE consists of, for example, 5 bits.

A calibration enable signal CALEN is input to the calibration circuit 101 (201, 301) via a pad 108. The calibration enable signal CALEN is a signal indicating a calibration operation period. For example, when the calibration enable signal CALEN transitions from a low level (L level) to a high level (H level), the calibration circuit 101 (201, 301) starts the calibration operation. Note that the calibration enable signal CALEN is not necessarily input from the outside of the interface circuit 100, but may be generated, for example, in the interface circuit 100.

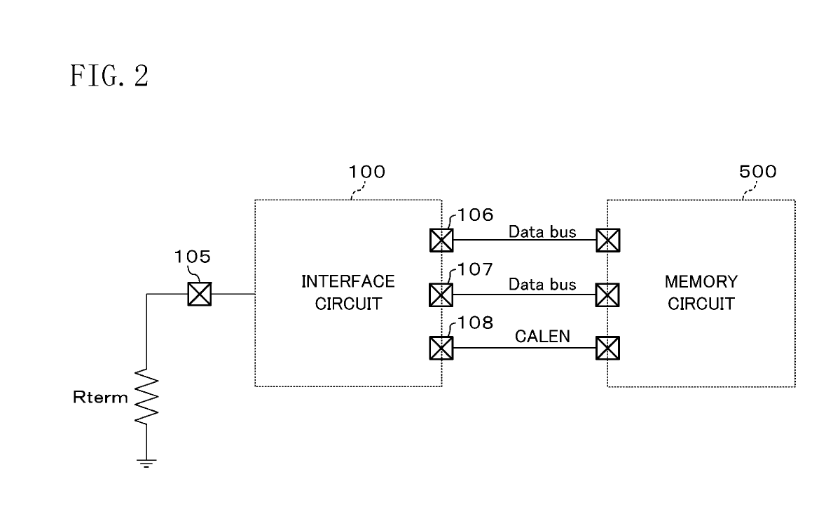

FIG. 2 is a view schematically illustrating a configuration in which the interface circuit 100 of FIG. 1 serves as a memory interface circuit. According to the configuration of FIG. 2, the interface circuit 100 is connected to a memory circuit 500, transmits write data from the transmission pad 106 via the data bus, and receives read data from the reception pad 107 via the data bus. The calibration enable signal CALEN is input to the interface circuit 100 from the memory circuit 500. Note that the interface circuit 100 of FIG. 1 may be used in applications other than the memory interface.

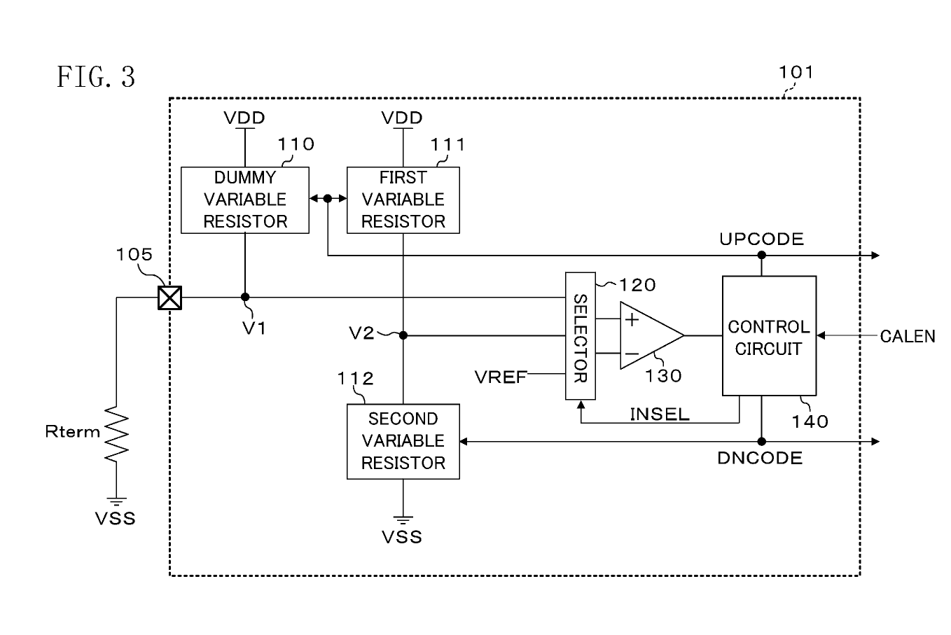

FIG. 3 is a circuit diagram illustrating a configuration of the calibration circuit 101 according to the present embodiment. In FIG. 3, a dummy variable resistor 110 is connected between a first power source supplying power supply potential VDD and the pad 105, and first and second variable resistors 111, 112 are connected in series between the first power source and a second power source supplying ground potential VSS. V1 is a first node between the dummy variable resistor 110 and the pad 105, and V2 is a second node between the first variable resistor 111 and the second variable resistor 112. The resistance values of the dummy variable resistor 110 and the first variable resistor 111 are controlled by a first variable-resistor control signal UPCODE output from a control circuit 140 which will be described later. The resistance value of the second variable resistor 112 is controlled by a second variable-resistor control signal DNCODE output from the control circuit 140. The relationship between the variable-resistor control signal and the resistance value may be determined such that, for example, the resistance value is a maximum value when all bits of the variable-resistor control signal are “0,” decreases as the signal value of the variable-resistor control signal increases, and is a minimum value when all the bits of the variable-resistor control signal are “1.” Note that the variable-resistor control signals UPCODE, DNCODE are used as the first and second control codes after the calibration operation is completed.

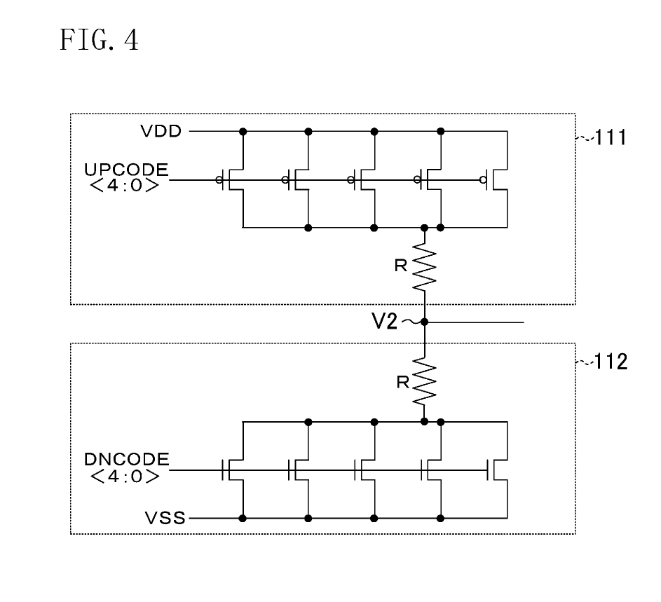

FIG. 4 illustrates example circuit configurations of the first and second variable resistors 111, 112. As illustrated in FIG. 4, the first variable resistor 111 and the second variable resistor 112 form a symmetrical structure with respect to the second node V2. Operation and a method for controlling the resistance value of the first variable resistor 111 are similar to those of the second variable resistor 112. The configuration and operation of the dummy variable resistor 110 are similar to those of the first variable resistor 111. Moreover, the configurations and operation of the variable resistance sections 104A, 104B illustrated in FIG. 1 are similar to those of the first and second variable resistors 111, 112.

Referring back to FIG. 3, a comparator 130 has a (+) input (positive input) and a (−) input (negative input). The comparator 130 outputs an H level, hereinafter H means high, when a voltage at the (+) input is higher than a voltage at the (−) input, whereas outputs an L level, hereinafter L means Low, when the voltage at the (+) input is lower than the voltage at the (−) input. A selector 120 receives a voltage at the first node V1 (hereinafter accordingly referred to as a voltage V1), a voltage at the second node V2 (hereinafter accordingly referred to as a voltage V2), and a reference voltage VREF, among which the selector 120 selects voltages to be applied to the (+) input and the (−) input of the comparator 130, and outputs the selected voltages. Selection operation of the selector 120 is controlled by a selector control signal INSEL being output from the control circuit 140. Moreover, the reference voltage VREF is set to, for example, a voltage at which the resistance values of the first and second variable resistors 111, 112 are each the same as the resistance value of the reference resistor Rterm.

The control circuit 140 receives an output of the comparator 130, and outputs the first and second variable-resistor control signals UPCODE, DNCODE, and the selector control signal INSEL. Moreover, the control circuit 140 receives the calibration enable signal CALEN, and performs the calibration operation according to the calibration enable signal CALEN.

<Description of Calibration Operation>

The calibration operation performed by the calibration circuit 101 having the above-described configuration will be described. In the present embodiment, the voltage V1 is first compared with the reference voltage VREF to determine the first control code (comparison step A). After that, the voltage V1 is compared with the voltage V2 to determine the second control code (comparison step B). Moreover, in each of the comparison steps A, B, the two voltages input to the comparator 130 are switched between the positive and negative inputs, and comparison operation is performed in both of the states.

—Comparison Step A—

The control circuit 140 controls the selector 120 by the selector control signal INSEL so that the voltage V1 is input to the (+) input of the comparator 130, and the reference voltage VREF is input to the (−) input of the comparator 130 (first comparison state).

In the first comparison state, the control circuit 140 monitors the output of the comparator 130 while varying the resistance value of the dummy variable resistor 110 by varying the first variable-resistor control signal UPCODE. A first variable-resistor control signal UPCODE at a time when the output of the comparator 130 is inverted is held as a possible control code ‘a’. For example, the first variable-resistor control signal UPCODE is counted up starting from a state in which all the bits are “0.” In this way, the resistance value of the dummy variable resistor 110 gradually decreases from the maximum value, and the voltage at the node V1 increases as the resistance ratio of the dummy variable resistor 110 to the reference resistor Rterm changes. When the voltage at the node V1 exceeds the reference voltage VREF, the output of the comparator 130 changes from the L level, which the comparator 130 has output, to the H level. A first variable-resistor control signal UPCODE at this time is held as the possible control code ‘a’.

Next, the control circuit 140 controls the selector 120 by the selector control signal INSEL so that the reference voltage VREF is input to the (+) input of the comparator 130, and the voltage V1 is input to the (−) input of the comparator 130 (second comparison state). That is, the input polarity of the comparator 130 is reversed.

In the second comparison state, the control circuit 140 monitors the output of the comparator 130 while varying the resistance value of the dummy variable resistor 110 by varying the first variable-resistor control signal UPCODE. A first variable-resistor control signal UPCODE at the time when the output of the comparator 130 is inverted is held as a possible control code b. For example, the first variable-resistor control signal UPCODE is counted down starting from a state in which all the bits are “1.” In this way, the resistance value of the dummy variable resistor 110 gradually increases from the minimum value, and the voltage at the node V1 decreases as the resistance ratio of the dummy variable resistor 110 to the reference resistor Rterm changes. When the voltage at the node V1 becomes smaller than the reference voltage VREF, the output of the comparator 130 changes from the L level, which the comparator 130 has output, to the H level. A first variable-resistor control signal UPCODE at this time is held as the possible control code b.

The control circuit 140 computes a mean value of the held possible control code ‘a’ and the held possible control code b, and determines that the mean value is the first control code to calibrate the terminating resistor. In the next comparison step B, the determined first control code is used as the first variable-resistor control signal UPCODE to set the resistance value of the first variable resistor 111.

—Comparison Step B—

The control circuit 140 controls the selector 120 by the selector control signal INSEL so that the voltage V1 is input to the (+) input of the comparator 130, and the voltage V2 is input to the (−) input of the comparator 130 (third comparison state).

In the third comparison state, the control circuit 140 monitors the output of the comparator 130 while varying the resistance value of the second variable resistor 112 by varying the second variable-resistor control signal DNCODE. A second variable-resistor control signal DNCODE at the time when the output of the comparator 130 is inverted is held as a possible control code c. For example, the second variable-resistor control signal DNCODE is counted up starting from a state in which all the bits are “0.” In this way, the resistance value of the second variable resistor 112 gradually decreases from the maximum value, and the voltage at the node V2 decreases as the resistance ratio of the first variable resistor 111 to the second variable resistor 112 changes. When the voltage at the node V2 becomes lower than the voltage V1, the output of the comparator 130 changes from the L level, which the comparator 130 has output, to the H level. A second variable-resistor control signal DNCODE at this time is held as the possible control code c.

Next, the control circuit 140 controls the selector 120 by the selector control signal INSEL so that the voltage V2 is input to the (+) input of the comparator 130, and the voltage V1 is input to the (−) input of the comparator 130 (fourth comparison state). That is, the input polarity of the comparator 130 is reversed.

In the fourth comparison state, the control circuit 140 monitors the output of the comparator 130 while varying the resistance value of the second variable resistor 112 by varying the second variable-resistor control signal DNCODE. A second variable-resistor control signal DNCODE at the time when the output of the comparator 130 is inverted is held as a possible control code d. For example, the second variable-resistor control signal DNCODE is counted down starting from a state in which all bits are “1.” In this way, the resistance value of the second variable resistor 112 gradually increases from the minimum value, and the voltage at the node V2 increases as the resistance ratio of the first variable resistor 111 to the second variable resistor 112 changes. When the voltage at the node V2 exceeds the voltage V1, the output of the comparator 130 changes from the L level, which the comparator 30 has output, to the H level. A second variable-resistor control signal DNCODE at this time is held as the possible control code d.

The control circuit 140 computes a mean value of the held possible control code c and the held possible control code d, and determines that the mean value is the second control code to calibrate the terminating resistor.

After the comparison steps A, B described above, the calibration operation is ended.

According to the calibration operation of the present embodiment, in each of the comparison steps A, B, the input polarity of the comparator 130 is reversed, where comparison is performed in both polarities to compute a mean value of the obtained possible control codes to obtain the control code. In this way, even when the comparator 130 includes an offset, it is possible to avoid the influence of the offset, so that it is possible to obtain a control code for calibration with a high degree of accuracy. Thus, the resistance values of the terminating resistors can be calibrated with a high degree of accuracy.

<Description of Recalibration Operation>

Moreover, in the present embodiment, when calibration is performed again after the calibration is performed once, calibration operation similar to the above-described calibration operation is performed. In this case, the first and second variable-resistor control signals UPCODE, DNCODE are preferably varied only within a predetermined range based on current calibration data, that is, the first and second control codes. That is, in the comparison step A, the first variable-resistor control signal UPCODE is varied within a range of the possible control code ‘a’±MA or a range of the possible control code b±MA (where MA is a positive integer), and in the comparison step B, the second variable-resistor control signal DNCODE is varied within a range of the possible control code c±MB or a range of the possible control code d±MB (where MB is a positive integer). In this way, it is possible to perform recalibration for a short time. Here, for example, each of MA and MB is 1, and the following operation is performed.

—Comparison Step A—

First, in the first comparison state, the first variable-resistor control signal UPCODE is set to “the possible control code a−1” to obtain an output of the comparator 130, and then, the first variable-resistor control signal UPCODE is set to “the possible control code a+1” to obtain an output of the comparator 130. When the outputs are the L level and the H level, the original possible control code ‘a’ is held as a new possible control code ‘a’. When both the outputs are L levels, the voltage V1 is lower than the reference voltage VREF, so that “the possible control code a+1” is held as the new possible control code ‘a’ to reduce the resistance value of the dummy variable resistor 110. When both the outputs are H levels, the voltage V1 is higher than the reference voltage VREF, so that “the possible control code a−1” is held as the new possible control code ‘a’ to increase the resistance value of the dummy variable resistor 110.

Next, in the second comparison state, the first variable-resistor control signal UPCODE is likewise set to “the possible control code b−1” to obtain an output of the comparator 130, and then, the first variable-resistor control signal UPCODE is set to “the possible control code b+1” to obtain an output of the comparator 130. When the outputs are the L level and the H level, the original possible control code b is held as a new possible control code b. When both the outputs are L levels, the voltage V1 is larger than the reference voltage VREF, so that “the possible control code b−1” is held as the new possible control code b to increase the resistance value of the dummy variable resistor 110. When both the outputs are H levels, the voltage V1 is smaller than the reference voltage VREF, so that “the possible control code b+1” is held as the new possible control code b to reduce the resistance value of the dummy variable resistor 110.

The control circuit 140 computes a mean value of the new possible control code ‘a’ and the new possible control code b, and determines that the mean value is the first control code to calibrate the terminating resistor. In the next comparison step B, the determined new first control code in the comparison step A is used as the first variable-resistor control signal UPCODE to set the resistance value of the first variable resistor 111.

—Comparison Step B—

First, in the third comparison state, the second variable-resistor control signal DNCODE is set to “the possible control code c−1” to obtain an output of the comparator 130, and then, the second variable-resistor control signal DNCODE is set to “the possible control code c+1” to obtain an output of the comparator 130. When the outputs are the L level and the H level, the original possible control code c is held as a new possible control code c. When both the outputs are L levels, the voltage V2 is larger than the voltage V1, so that “the possible control code c+1” is held as the new possible control code c to reduce the resistance value of the second variable resistor 112. When both the outputs are H levels, the voltage V2 is smaller than the voltage V1, so that “the possible control code c−1” is held as the new possible control code c to increase the resistance value of the second variable resistor 112.

Next, in the fourth comparison state, the second variable-resistor control signal DNCODE is likewise set to “the possible control code d−1” to obtain an output of the comparator 130, and then, the second variable-resistor control signal DNCODE is set to “the possible control code d+1” to obtain an output of the comparator 130. When the outputs are the L level and the H level, the original possible control code d is held as a new possible control code d. When both the outputs are L levels, the voltage V2 is smaller than the voltage V1, so that “the possible control code d−1” is held as the new possible control code d to increase the resistance value of the second variable resistor 112. When both the outputs are H levels, the voltage V2 is larger than the voltage V1, so that “the possible control code d+1” is held as the new possible control code d to reduce the resistance value of the second variable resistor 112.

The control circuit 140 computes a mean value of the new possible control code c and the new possible control code d, and determines that the mean value is the second control code to calibrate the terminating resistor.

As described above, in performing the recalibration, the first and second variable-resistor control signals UPCODE, DNCODE are varied only within a predetermined range based on current calibration data, so that it is possible to perform the recalibration for a short time. Thus, the recalibration can be rapidly performed for a short time even when, for example, the resistance value of the terminating resistor varies due to a change in surrounding temperature, or the like.

Note that if, for example, a continuous period of time required for the recalibration operation is not ensured to perform the recalibration, the operation may be divided and performed in a plurality of periods. In this way, the recalibration operation can be stepwise performed even when the continuous period of time is not ensured, for example, in the case where the resistance value of the terminating resistor varies due to a change in surrounding temperature. Thus, it is possible to rapidly perform the recalibration for a short time.

### Second Embodiment

A configuration of an interface circuit according to a second embodiment is similar to that of FIG. 1 described in the first embodiment, and a detailed description thereof is omitted.

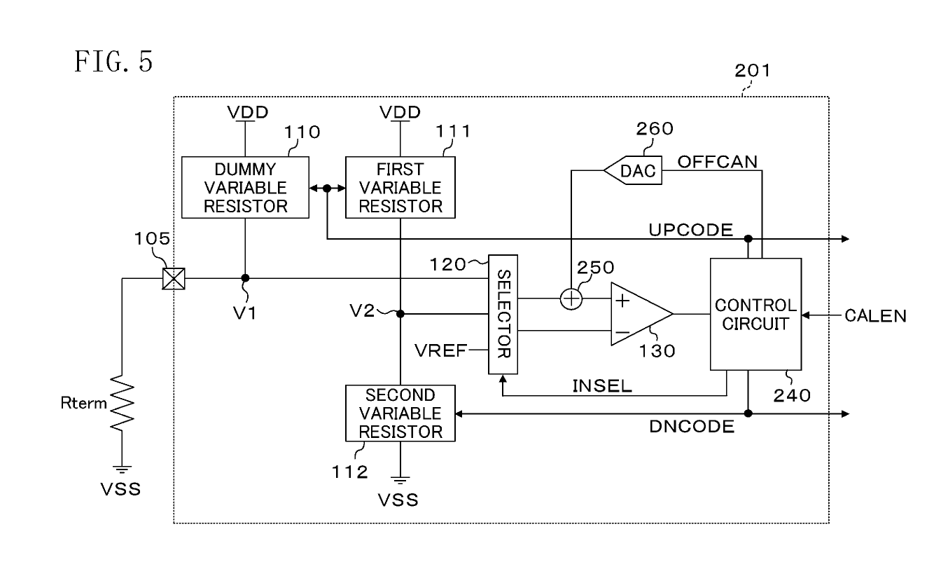

FIG. 5 is a circuit diagram illustrating a configuration of a calibration circuit 201 according to the present embodiment. In FIG. 5, the same reference numerals as those shown in FIG. 3 are used to represent elements identical with or equivalent to those of FIG. 3, and a detailed description thereof is be omitted. In FIG. 5, reference number 260 denotes a D/A converter configured to cancel an offset of the comparator 130, and reference number 250 denotes an adder configured to add an output of the D/A converter 260 to the (+) input of the comparator 130. A control circuit 240 outputs an offset cancellation signal OFFCAN which is input to the D/A converter 260, in addition to first and second variable-resistor control signals UPCODE, DNCODE and a selector control signal INSEL. The D/A converter 260 converts the offset cancellation signal OFFCAN to an analog value, and outputs the analog value. The adder 250 adds an output of the selector 120 to the output of the D/A converter 260, and supplies the obtained result to the (+) input of the comparator 130. Note that the adder 250 may be provided upstream of the (−) input of the comparator 130.

<Description of Calibration Operation>

Calibration operation performed by the calibration circuit 201 having the above configuration will be described. In the present embodiment, offset cancellation data is first obtained to cancel the offset of the comparator 130 (offset detection step). A voltage V1 is compared with a reference voltage VREF with the offset being canceled, thereby determining a first control code (comparison step A). Then, the voltage V1 is compared with a voltage V2 to determine a second control code (comparison step B).

—Offset Detection Step—

The control circuit 240 controls the selector 120 by the selector control signal INSEL so that the reference voltage VREF is input to both the (+) input and the (−) input of the comparator 130 (first comparison state).

In the first comparison state, the control circuit 240 monitors an output of the comparator 130 while increasing or reducing an output voltage of the adder 250 from the reference voltage VREF by varying the offset cancellation signal OFFCAN. A value of the offset cancellation signal OFFCAN at a time when the output of the comparator 130 is inverted is obtained, and the obtained value is held as the offset cancellation data. In the following comparison steps A, B, the offset cancellation data is supplied to the D/A converter 260, and the D/A converter 260 outputs the analog value based on the offset cancellation data, and the analog value is added to the (+) input of the comparator 130. This cancels the influence of the offset of the comparator 130.

—Comparison Step A—

The control circuit 240 controls the selector 120 by the selector control signal INSEL so that the voltage V1 is input to the (+) input of the comparator 130, and the reference voltage VREF is input to the (−) input of the comparator 130 (second comparison state).

In the second comparison state, the control circuit 240 monitors the output of the comparator 130 while varying the resistance value of the dummy variable resistor 110 by varying the first variable-resistor control signal UPCODE. A first variable-resistor control signal UPCODE at the time when the output of the comparator 130 is inverted is defined as the first control code to calibrate the terminating resistor. For example, the first variable-resistor control signal UPCODE is counted up starting from a state in which all the bits are “0.” In this way, the resistance value of the dummy variable resistor 110 gradually decreases from the maximum value, and the voltage at the node V1 increases as the resistance ratio of the dummy variable resistor 110 to the reference resistor Rterm changes. When the voltage at the node V1 exceeds the reference voltage VREF, the output of the comparator 130 changes from the L level, which the comparator 130 has output, to the H level. A first variable-resistor control signal UPCODE at this time is held as the first control code. In the next comparison step B, the determined first control code is used as the first variable-resistor control signal UPCODE to set the resistance value of the first variable resistor 111.

—Comparison Step B—

The control circuit 240 controls the selector 120 by the selector control signal INSEL so that the voltage V1 is input to the (+) input of the comparator 130, and the voltage V2 is input to the (−) input of the comparator 130 (third comparison state).

In the third comparison state, the control circuit 240 monitors the output of the comparator 130 while varying the resistance value of the second variable resistor 112 by varying the second variable-resistor control signal DNCODE. A second variable-resistor control signal DNCODE at the time when the output of the comparator 130 is inverted is defined as the second control code to calibrate the terminating resistor. For example, the second variable-resistor control signal DNCODE is counted up starting from a state in which all the bits are “0.” In this way, the resistance value of the second variable resistor 112 gradually decreases from the maximum value, and the voltage at the node V2 decreases as the resistance ratio of the first variable resistor 111 to the second variable resistor 112 changes. When the voltage at the node V2 becomes lower than the voltage V1, the output of the comparator 130 changes from the L level, which the comparator 130 has output, to the H level. A second variable-resistor control signal DNCODE at this time is held as the second control code.

After the offset detection step and the comparison steps A, B described above, the calibration operation is ended.

According to the calibration operation of the present embodiment, before the comparison steps A, B, an analog value according to an offset cancellation signal is added to one of the inputs of the comparator 130 in the offset detection step, thereby obtaining offset cancellation data. In this way, it is possible to avoid the influence of the offset of the comparator 130, so that it is possible to obtain calibration data with a high degree of accuracy. Thus, the resistance values of the terminating resistors can be calibrated with a high degree of accuracy.

<Description of Recalibration Operation>

Moreover, in the present embodiment, when calibration is performed again after the calibration is performed once, calibration operation similar to the above-described calibration operation is performed. In this case, the first and second variable-resistor control signals UPCODE, DNCODE are preferably varied only within a predetermined range based on current calibration data. That is, in the comparison step A, the first variable-resistor control signal UPCODE is varied within a range of the first control code±MA (where MA is a positive integer), and in the comparison step B, the second variable-resistor control signal DNCODE is varied within a range of the second control code±MB (where MB is a positive integer). In this way, it is possible to perform recalibration for a short time. Here, for example, each of MA and MB is 1, and the following operation is performed.

—Comparison Step A—

In the second comparison state, the first variable-resistor control signal UPCODE is set to “the first control code−1” to obtain an output of the comparator 130, and then the first variable-resistor control signal UPCODE is set to “the first control code+1” to obtain an output of the comparator 130. When the outputs are the L level and the H level, the original first control code is held as a new first control code. When both the outputs are L levels, the voltage V1 is lower than the reference voltage VREF, so that “the first control code+1” is held as the new first control code to reduce the resistance value of the dummy variable resistor 110. When both the outputs are H levels, the voltage V1 is higher than the reference voltage VREF, so that “the first control code−1” is held as the new first control code to increase the resistance value of the dummy variable resistor 110. In the next comparison step B, the determined new first control code in the comparison step A is used as the first variable-resistor control signal UPCODE to set the resistance value of the first variable resistor 111.

—Comparison Step B—

In the third comparison state, the second variable-resistor control signal DNCODE is set to “the second control code−1” to obtain an output of the comparator 130, and then the second variable-resistor control signal DNCODE is set to “the second control code+1” to obtain an output of the comparator 130. When the outputs are the L level and the H level, the original second control code is held as a new second control code. When both the outputs are L levels, the voltage V2 is larger than the voltage V1, so that “the second control code+1” is held as the new possible control code c to reduce the resistance value of the second variable resistor 112. When both the outputs are H levels, the voltage V2 is smaller than the voltage V1, so that “the second control code−1” is held as the new second control code to increase the resistance value of the second variable resistor 112.

As described above, in performing the recalibration, the first and second variable-resistor control signals UPCODE, DNCODE are varied only within a predetermined range based on current calibration data, so that it is possible to perform the recalibration for a short time. Thus, the recalibration can be rapidly performed for a short time even when, for example, the resistance value of the terminating resistor varies due to a change in surrounding temperature, or the like.

Note that in performing the recalibration, new calibration data may be obtained after the offset detection step is performed to obtain the offset cancellation data again. In this way, it is possible to obtain calibration data with a high degree of accuracy even when, for example, the surrounding temperature varies.

Alternatively, if, for example, a continuous period of time required for the recalibration operation is not ensured to perform the recalibration, the operation may be divided and performed in a plurality of periods. In this way, the recalibration operation can be stepwise performed even when the continuous period of time is not ensured, for example, in the case where the resistance value of the terminating resistor varies due to a change in surrounding temperature. Thus, it is possible to rapidly perform the recalibration for a short time.

### Third Embodiment

A configuration of an interface circuit according to a third embodiment is similar to that of FIG. 1 described in the first embodiment, and a detailed description thereof is omitted.

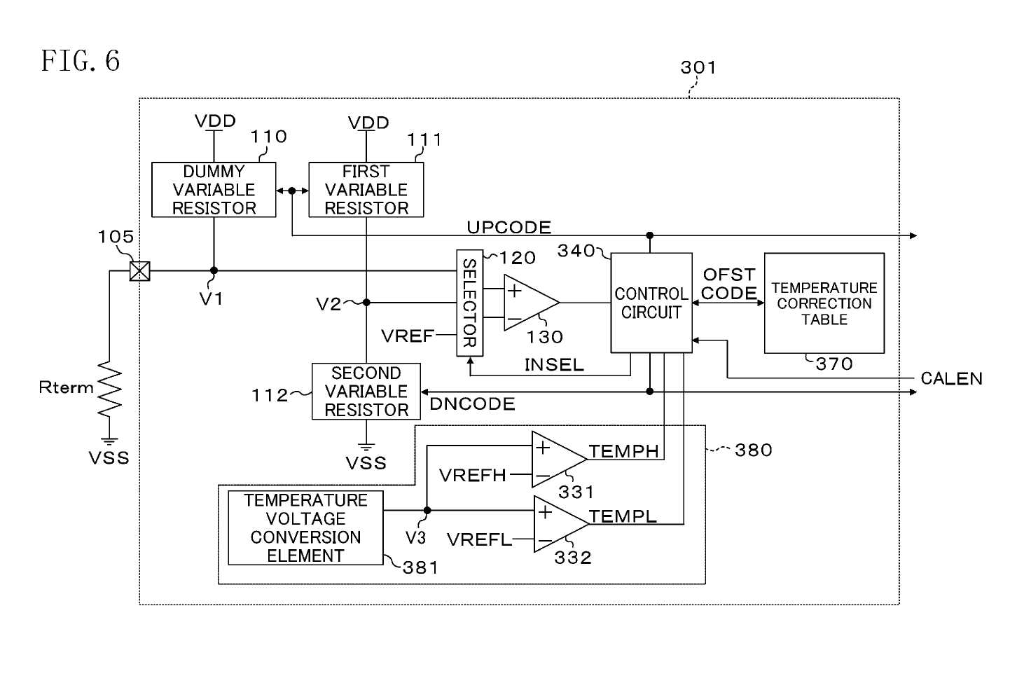

FIG. 6 is a circuit diagram illustrating a configuration of a calibration circuit 301 according to the present embodiment. In FIG. 6, the same reference numerals as those shown in FIG. 3 are used to represent elements identical with or equivalent to those of FIG. 3, and a detailed description thereof is omitted. In FIG. 6, reference number 380 denotes a temperature detection section, and reference number 370 denotes a temperature correction table. The temperature detection section 380 includes a temperature voltage conversion element 381, and comparators 331, 332 configured to compare an output of the temperature voltage conversion element 381 with temperature detecting reference voltages VREFH, VREFL which are different from each other. The comparators 331, 332 form a temperature detecting comparison section. The reference voltage VREFH has a voltage level to detect a high temperature, and the reference voltage VREFL has a voltage level to detect a low temperature. Outputs TEMPH, TEMPL of the comparators 331, 332 are supplied to a control circuit 340. The temperature correction table 370 stores temperature correction amounts of calibration data in relation to the outputs TEMPH, TEMPL of the comparators 331, 332.

Operation of the calibration circuit 301 having the above-described configuration will be described. In the present embodiment, calibration operation is performed in the same manner as in the first embodiment.

In the present embodiment, after calibration is performed once, when calibration is performed again, temperature correction of the calibration data is performed. That is, the temperature voltage conversion element 381 outputs a voltage based on surrounding temperature, and the output is compared with the reference voltages VREFH, VREFL by the comparators 331, 332, respectively. The control circuit 340 receives the outputs TEMPH, TEMPL of the comparators 331, 332, and refers to the temperature correction table 370 by using the outputs TEMPH, TEMPL, thereby obtaining a temperature correction amount OFSTCODE. The temperature correction amount OFSTCODE is added to possible control codes a, b, c, d before performing recalibration. After that, the recalibration is performed in the same manner as in the first embodiment.

As described above, according to the present embodiment, to perform the recalibration, the temperature correction amount OFTCODE of the calibration data is obtained before the recalibration. In this way, variations of resistance values due to a change in surrounding temperature can be corrected for a shorter time.

Although the present embodiment has been described in combination with the first embodiment, the present embodiment may be combined with, for example, the second embodiment. That is, the configuration of the interface circuit 201 illustrated in FIG. 5 may be provided with the temperature detection section 380 and the temperature correction table 370 illustrated in FIG. 6, and the temperature correction amount OFTCODE of the calibration data may be obtained before the recalibration as in the present embodiment. Then, the temperature correction amount OFSTCODE may be added to the first and second control codes before performing the recalibration.

Although the temperature detecting comparison section of the present embodiment includes two comparators, two or more comparators may be provided. Increasing the number of comparators to increase the number of temperature detecting voltage levels allows more precise correction of the variations of the resistance values due to a change in surrounding temperature.

Alternatively, in each of the above embodiments, the control circuit 140, 240, or 340 may repeatedly perform the recalibration after the calibration is performed once. That is, when the recalibration is continuously performed, the variations of the resistance values due to a change in surrounding temperature are continuously corrected, so that preferable signal transmission characteristics are always ensured.

In the present invention, calibration of the terminating resistor of the bus to a preferable resistance value can be ensured, and thus, for example, the present invention can be useful for memory interface circuits in which preferable signal transmission characteristics have to be ensured.

What is claimed is:

1. An interface circuit configured to calibrate a resistance value of a terminating resistor, the interface circuit comprising:
a variable resistance section serving as the terminating resistor;
a pad to which a reference resistor is externally connected; and
a calibration circuit which is connected to the pad, and is configured to output calibration data to the variable resistance section to control the resistance value, the calibration circuit including
a dummy variable resistor connected between a first power source and the pad,
first and second variable resistors connected in series between the first power source and a second power source,
a comparator having a positive input and a negative input,
a selector configured to receive a voltage at a first node between the dummy variable resistor and the pad, a voltage at a second node between the first and second variable resistors, and a reference voltage, to select, among the voltages, respective voltages to be applied to the positive input and the negative input of the comparator, and to output the selected voltages, and
a control circuit configured to receive the output of the comparator, and to output a first variable-resistor control signal for controlling resistance values of the dummy variable resistor and the first variable resistor, a second variable-resistor control signal for controlling a resistance value of the second variable resistor, and a selector control signal for controlling the selector, wherein
in performing calibration, the control circuit monitors the output of the comparator while varying the first or second variable-resistor control signal in a state of controlling the selector by the selector control signal so that the voltage at the first node and the reference voltage, or the voltage at the first node and the voltage at the second node are applied to the comparator, and obtains the calibration data based on a signal value of the first or second variable-resistor control signal at a time when the output of the comparator is changed, and
the control circuit obtains the signal value of the first or second variable-resistor control signal at the time when the output of the comparator is changed in a state where the voltage at the first node and the reference voltage, or the voltage at the first node and the voltage at the second node are input to the positive and negative inputs of the comparator, respectively, and in a state where the voltage at the first node and the reference voltage, or the voltage at the first node and the voltage at the second node are input to the negative and positive inputs of the comparator, respectively, and obtains the calibration data using a mean value of the obtained signal values.

2. The interface circuit of claim 1, wherein
in performing recalibration, the control circuit varies the first or second variable-resistor control signal within a predetermined range based on current calibration data to obtain new calibration data.

3. An interface circuit configured to calibrate a resistance value of a terminating resistor, the interface circuit comprising:
a variable resistance section serving as the terminating resistor;
a pad to which a reference resistor is externally connected; and
a calibration circuit which is connected to the pad, and is configured to output calibration data to the variable resistance section to control the resistance value, the calibration circuit including
a dummy variable resistor connected between a first power source and the pad,
first and second variable resistors connected in series between the first power source and a second power source,
a comparator having a positive input and a negative input,
a selector configured to receive a voltage at a first node between the dummy variable resistor and the pad, a voltage at a second node between the first and second variable resistors, and a reference voltage, to select, among the voltages, respective voltages to be applied to the positive input and the negative input of the comparator, and to output the selected voltages,
a D/A converter which is used to cancel an offset of the comparator,
an adder configured to add an output of the D/A converter to the positive input or the negative input of the comparator, and
a control circuit configured to receive the output of the comparator, and to output a first variable-resistor control signal for controlling resistance values of the dummy variable resistor and the first variable resistor, a second variable-resistor control signal for controlling a resistance value of the second variable resistor, a selector control signal for controlling the selector, and an offset cancellation signal to be input to the DA converter, wherein
in performing calibration, the control circuit monitors the output of the comparator while varying the first or second variable-resistor control signal in a state of controlling the selector by the selector control signal so that the voltage at the first node and the reference voltage, or the voltage at the first node and the voltage at the second node are applied to the comparator, and obtains the calibration data based on a signal value of the first or second variable-resistor control signal at a time when the output of the comparator is changed, and
before the calibration data is obtained, the control circuit monitors the output of the comparator while varying the offset cancellation signal in a state of controlling the selector by the selector control signal so that the reference voltage is applied to both the positive and negative inputs of the comparator, and obtains offset cancellation data based on a signal value of the offset cancellation signal at the time when the output is changed, and
the control circuit supplies the offset cancellation data to the D/A converter in performing the calibration.

4. The interface circuit of claim 3, wherein
in performing recalibration, the control circuit varies the first or second variable-resistor control signal within a predetermined range based on current calibration data to obtain new calibration data.

5. The interface circuit of claim 4, wherein
in performing recalibration, the control circuit obtains the new calibration data after the offset cancellation data is obtained again.

6. The interface circuit of claim 2, further comprising:
a temperature voltage conversion element;
a temperature detecting comparison section configured to compare an output of the temperature voltage conversion element with at least two or more temperature detecting reference voltages which are different from each other; and
a temperature correction table in which a temperature correction amount of the calibration data is stored in relation to an output of the temperature detecting comparison section, wherein
in performing recalibration, the control circuit receives the output of the temperature detecting comparison section, and refers to the temperature correction table by using the output to obtain the temperature correction amount of the calibration data.

7. The interface circuit of claim 2, wherein
the control circuit performs processing for the recalibration in divided periods.

8. The interface circuit of claim 2, wherein
the control circuit repeatedly performs the recalibration.

9. The interface circuit of claim 4, further comprising:
a temperature voltage conversion element;
a temperature detecting comparison section configured to compare an output of the temperature voltage conversion element with at least two or more temperature detecting reference voltages which are different from each other; and
a temperature correction table in which a temperature correction amount of the calibration data is stored in relation to an output of the temperature detecting comparison section, wherein
in performing recalibration, the control circuit receives the output of the temperature detecting comparison section, and refers to the temperature correction table by using the output to obtain the temperature correction amount of the calibration data.

10. The interface circuit of claim 4, wherein
the control circuit performs processing for the recalibration in divided periods.

11. The interface circuit of claim 4, wherein
the control circuit repeatedly performs the recalibration.
